(19) United States
(12) Patent Application Publication
(10) Pub. No.: US 2024/0235534 A1
(43) Pub. Date: Jul. 11, 2024

(54) OSCILLATOR WITH SCHMITT TRIGGER

(71) Applicant: Atmosic Technologies, Inc., Campbell, CA (US)

(72) Inventor: Gareth Yeo, Sunnyvale, CA (US)

(73) Assignee: Atmosic Technologies, Inc., Campbell, CA (US)

(21) Appl. No.: 18/395,997

(22) Filed: Dec. 26, 2023

Related U.S. Application Data
(60) Provisional application No. 63/437,354, filed on Jan. 5, 2023.

(51) Int. Cl. H03K 3/037; H03K 3/011; H03K 3/03; H03K 5/133

(52) U.S. Cl. CPC H03K 3/0377; H03K 3/011; H03K 3/0315; H03K 5/133

(57) ABSTRACT

A programmable ring oscillator for a wireless device is disclosed. The programmable ring oscillator includes a Schmitt trigger, first and second CMOS inverters, first and second resistors, and a capacitor. The Schmitt trigger includes an input coupled to a first node, a control terminal coupled to a configuration signal, and an output. The first CMOS inverter includes an input coupled to the output of the Schmitt trigger and an output coupled to a second node. The second CMOS inverter includes an input coupled to the second node and an output coupled to an output terminal configured to provide an output signal having a oscillating frequency. The first resistor is coupled between the output terminal and a third node, and the second resistor is coupled between the third node and the first node. The capacitor is coupled between the second node and the third node.

### CROSS-REFERENCE TO RELATED APPLICATION

This patent application claims priority to U.S. Provisional Patent Application No. 63/437,354 entitled “OSCILLATOR WITH SCHMITT TRIGGER” and filed on Jan. 5, 2023, which is assigned to the assignee hereof. The disclosures of all prior applications are considered part of and are incorporated by reference in this patent application.

### TECHNICAL FIELD

The present implementations relate generally to wireless devices, and specifically to oscillators used in wireless devices.

### BACKGROUND OF RELATED ART

Wireless devices (such as Wi-Fi devices, Bluetooth devices, wireless sensors, and IoT devices and the like) are battery powered to provide mobility and convenience. Reducing the power consumption of wireless devices may increase the time between battery charging and extend battery life. Some wireless devices include an energy harvester that can capture energy associated with radio-frequency (RF) signals and convert the captured energy into a voltage that can be used to charge the battery and to power various more application loads (such as microprocessor and transceiver chains) of a respective wireless device. These wireless devices typically include a control circuit coupled between the energy harvester, the battery, and the application loads that can manage charging and power delivery operations associated with the energy harvester. When the wireless device is powered-on, the control circuit initially uses the harvested energy to charge a capacitor (or other small charge storage device). When the capacitor has accumulated sufficient charge to power at least some of the application loads, the control circuit uses the harvested energy to charge the battery.

When the charge stored on the capacitor falls below a certain level and/or there is insufficient nearby electromagnetic radiation from which to harvest energy, the wireless device may enter a low-power state during which various components are powered down or placed in a sleep state to minimize power consumption. For example, while in the low-power state, the wireless device may disable crystal oscillators that generate various system clocks with ring oscillators that are less accurate but consume less power than the crystal oscillators. Further improvements in ring oscillators are needed.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description presented later.

One innovative aspect of the subject matter described in this disclosure can be implemented as a programmable ring oscillator in a wireless device. The wireless device includes a programmable ring oscillator that can generate various clock signals for the wireless device. In some implementations, the programmable ring oscillator includes a Schmitt trigger, first and second CMOS inverters, first and second resistors, and a capacitor. The Schmitt trigger includes an input coupled to a first node, a control terminal coupled to a configuration signal, and an output. The first CMOS inverter includes an input coupled to the output of the Schmitt trigger and an output coupled to a second node. The second CMOS inverter includes an input coupled to the second node and an output coupled to an output terminal of the programmable ring oscillator. The output terminal provides an output signal having a oscillating frequency. The first resistor is coupled between the output terminal and a third node, and the second resistor is coupled between the third node and the first node. The capacitor is coupled between the second node and the third node. In some instances, the oscillating frequency is based on an RC time constant of the first resistor, the second resistor, and the capacitor. In various aspects, the Schmitt trigger may be an inverting comparator. In some aspects, the programmable ring oscillator may be a relaxation oscillator.

The Schmitt trigger includes power terminals coupled to a supply voltage and ground potential, and may include input hysteresis having a relatively low threshold voltage and a relatively high threshold voltage. In some implementations, the relatively low threshold voltage may be equal to ground potential and the relatively high threshold voltage may be equal to the supply voltage, and a difference between the relatively low threshold voltage and the relatively high threshold voltage is proportional to the supply voltage. In some instances, the relatively low and high threshold voltages may be based on one or more values of the configuration signal. In some aspects, the one or more values of the configuration signal may be based at least in part on an instantaneous value of the supply voltage, changes in the supply voltage, or both. In other aspects, the one or more values of the configuration signal may be based at least in part on an operating temperature of the programmable ring oscillator. In some other aspects, the one or more values of the configuration signal are based at least in part on low-power parameters associated with a wireless device.

### BRIEF DESCRIPTION OF THE DRAWINGS

Aspects of the present disclosure are illustrated by way of example and are not intended to be limited by the figures of the accompanying drawings.

FIG. 1 shows a wireless communication system within which aspects of the present disclosure may be implemented.

FIG. 2 shows a block diagram of an example wireless device.

FIG. 3 shows a block diagram of a clock system that can be used in the wireless device of FIG. 2.

FIG. 4 shows a block diagram of a ring oscillator that can be used in the wireless device of FIG. 2.

FIG. 5 shows a graph depicting input and output voltage waveforms associated with the oscillator circuit of FIG. 4.

FIG. 6 shows a block diagram of an example ring oscillator, according to some implementations.

Like numbers reference like elements throughout the drawings and specification.

### DETAILED DESCRIPTION

The following description is directed to certain implementations for the purpose of describing innovative aspects of this disclosure. However, a person having ordinary skill in the art will readily recognize that the teachings herein can be applied in a multitude of different ways. The described implementations can be implemented in any device, system, or network that is capable of transmitting and receiving radio frequency (RF) signals according to one or more of the Institute of Electrical and Electronics Engineers (IEEE) 802.11 standards, the IEEE 802.15 standards, the Bluetooth® communication protocols defined by the Bluetooth Special Interest Group (SIG), or the Long Term Evolution (LTE) and Fifth Generation New Radio (5G NR) standards promulgated by the 3rd Generation Partnership Project (3GPP), among others. These RF signals may be transmitted or received using one or more of code division multiple access (CDMA), time division multiple access (TDMA), frequency division multiple access (FDMA), orthogonal FDMA (OFDMA), single-carrier FDMA (SC-FDMA), single-user (SU) multiple-input multiple-output (MIMO), and multi-user (MU) MIMO.

In the following description, numerous specific details are set forth such as examples of specific components, circuits, and processes to provide a thorough understanding of the disclosure. The term “coupled” as used herein means coupled directly to or coupled through one or more intervening components or circuits. Also, in the following description and for purposes of explanation, specific nomenclature is set forth to provide a thorough understanding of the example embodiments. However, it will be apparent to one skilled in the art that these specific details may not be required to practice the example embodiments. In other instances, well-known circuits and devices are shown in block diagram form to avoid obscuring the disclosure. Any of the signals provided over various buses described herein may be time-multiplexed with other signals and provided over one or more common buses. Additionally, the interconnection between circuit elements or software blocks may be shown as buses or as single signal lines. Each of the buses may alternatively be a single signal line, and each of the single signal lines may alternatively be buses, and a single line or bus might represent any one or more of a myriad of physical or logical mechanisms for communication between components. The example implementations are not to be construed as limited to specific examples described herein but rather to include within their scope all embodiments defined by the appended claims.

The various illustrative logical blocks, modules, circuits, and instructions described in connection with the implementations disclosed herein may be executed by one or more processors, such as one or more digital signal processors (DSPs), general purpose microprocessors, application specific integrated circuits (ASICs), application specific instruction set processors (ASIPs), field programmable gate arrays (FPGAs), or other equivalent integrated or discrete logic circuitry. The term “processor” as used herein may refer to any of the foregoing structures or any other structure suitable for implementation of the techniques described herein. In addition, the functionality described herein may be provided within dedicated software modules or hardware modules configured as described herein. Also, the techniques disclosed herein may be fully implemented in one or more circuits or logic elements. A general-purpose processor may be a microprocessor, or may be any conventional processor, controller, microcontroller, or state machine. A processor may also be implemented as a combination of computing devices such as a DSP and a microprocessor, a plurality of microprocessors, or any other suitable configuration.

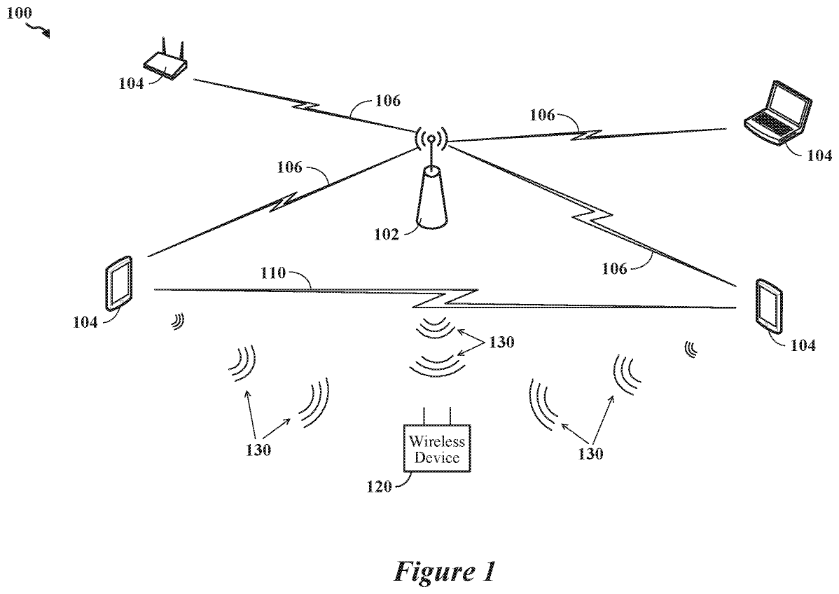

FIG. 1 shows a wireless environment 100 within which aspects of the present disclosure may be implemented. The wireless environment 100 may include any number of wireless communication devices such as a base station 102, various client devices 104, and a wireless device 120. Although only one base station 102 is shown in the example of FIG. 1, in other implementations, the wireless environment 100 may include multiple base stations 102. Each of the client devices 104 also may be referred to as a wireless station (STA), a mobile station (MS), a mobile device, a mobile handset, a wireless handset, an access terminal (AT), a user equipment (UE), a subscriber station (SS), or a subscriber unit, among other examples. The client devices 104 may be various devices such as mobile phones, personal digital assistant (PDAs), other handheld devices, netbooks, notebook computers, tablet computers, laptops, display devices (for example, TVs, computer monitors, navigation systems, among others), music or other audio or stereo devices, remote control devices, printers, kitchen or other household appliances, key fobs (for example, for passive keyless entry and start (PKES) systems), among other examples.

In some implementations, the wireless environment 100 may be associated with a wireless local area network (WLAN) such as a Wi-Fi network that implements one or more of the IEEE 802.11 family of wireless communication standards or a cellular network that implements one or more of the 3GPP communication protocols. In other implementations, the wireless environment 100 may be associated with a mesh network operating according to the EasyMesh™ specification provided by the Wi-Fi Alliance or a wireless personal area network (WPAN) that implements one or more of the Bluetooth or Bluetooth Low Energy (BLE) Specifications. For these implementations, the client devices 104 can communicate with one another over direct communication links (such as BLE connections or mesh links), and the base station 102 may not be needed. In some other implementations, RF signals transmitted by base station 102 and client devices 104 may be based on proprietary, military, or other non-commercial communication standards.

The wireless device 120 includes an energy harvester that can convert energy associated with RF signals transmitted by base station 102, client devices 104, and other sources of electromagnetic radiation into power that can be used to power one or more components of the wireless device 120. In some instances, the wireless device 120 may include a battery and a small charge store device (such as a capacitor) that can store harvested energy for subsequent use in powering various components of the wireless device 120. In other instances, the wireless device 120 may not include a battery. For example, the wireless device 120 may be an IoT device including (but not limited to) environmental sensor (such as temperature sensors, air pressure sensors, humidity sensors, etc.), a door position sensor, a window position sensor, a door or building access card, or an ID device for which a battery or external power source may not be feasible, available, or even desirable. In some aspects, the wireless device 120 may be powered entirely by energy harvested from RF signals and other sources of electromagnetic radiation.

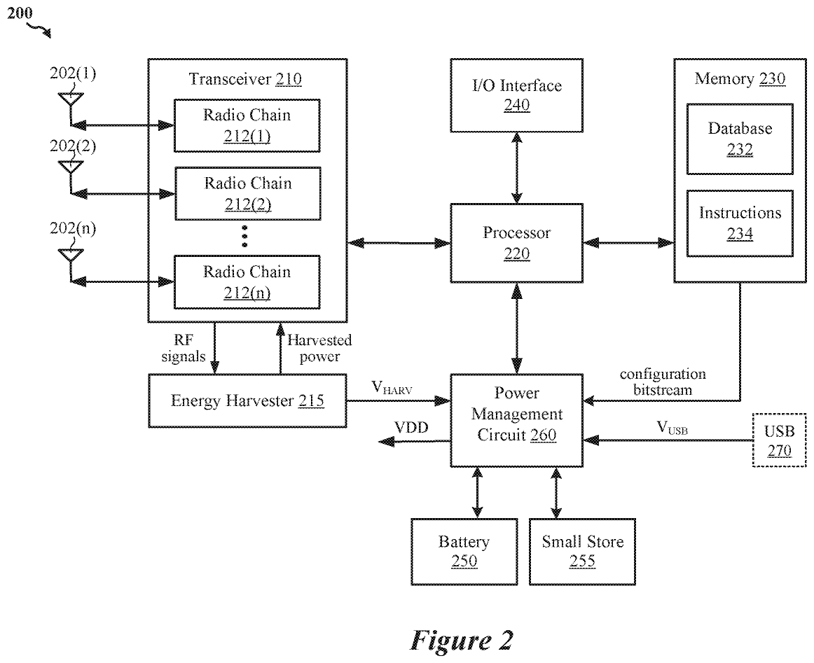

FIG. 2 shows a block diagram of a wireless device 200 in accordance with various aspects of the present disclosure. In some implementations, the wireless device 200 may be an example of the wireless device 120 of FIG. 1. The wireless device 200 includes antennas 202(1)-202(n), a transceiver 210, a baseband processor 220, a memory 230, an input/output (I/O) interface 240, a battery 250, and a charging control circuit 260. The antennas 202(1)-202(n) can transmit and receive RF signals of various frequencies to and from other wireless devices. For example, in some instances, the antennas 202(1)-202(n) can transmit and receive RF signals in one or more of the 900 MHz frequency band, the 2.4 GHz frequency band, the 5 GHz frequency band, the 6 GHz frequency band, or the 60 GHz frequency band. In the example of Figure, the wireless device 200 is shown to include multiple antennas 212(1)-212(n) that can provide antenna diversity, enable multiple-input, multiple-output (MIMO) communications, and/or transmit or receive multiple spatial streams to or from other wireless devices. In some other implementations, the wireless device 200 may include only one antenna.

The I/O interface 240 may include any suitable mechanism, interface, or device to receive input (such as commands) from the user and to provide output to the user. For example, the I/O interface 240 may include (but are not limited to) a graphical user interface, keyboard, mouse, microphone, speakers, and so on. Although not shown for simplicity, in some instances, the wireless device 200 may also include a display upon which items may be presented to a user. In some aspects, the display may be a touch-screen display that allows the user to interact with various features, programs, and operations of the wireless device 200.

The transceiver 210 may be coupled to the antennas 202(1)-202(n), either directly or through an antenna selection circuit (not shown for simplicity). The transceiver 210 may be used to transmit signals to and receive signals from other wireless devices such as (but not limited to) the base station 102 and the client devices 104 of FIG. 1. The transceiver 210 may also be used to scan the surrounding environment to detect and identify nearby wireless devices. The transceiver 210 may include a plurality of radio chains 212(1)-212(n) that can be used to communicate with other wireless devices according to one or more wireless communication protocols such as (but not limited to) WLAN communications, Bluetooth communications, or cellular communications. Although not shown in FIG. 2 for simplicity, each of the radio chains 212(1)-212(n) may include a transmit chain and a receive chain. Each transmit chain may receive data to be transmitted from the baseband processor 220, upconvert the received data from a baseband frequency to a carrier frequency (such as 2.4 GHz or 5 GHz) and transmit the upconverted data to one or more other wireless devices via one or both antennas 202(1)-202(n). Each receive chain may receive data transmitted from other wireless devices via one or both antennas 202(1)-202(n), down-convert the received data from the carrier frequency to the baseband frequency and provide the down-converted data to the baseband processor 220. In some instances, the wireless device 200 may be configured for MIMO operations. The MIMO operations may include SU-MIMO operations and MU-MIMO operations. In some aspects, the wireless device 200 may also be configured for OFDMA communications or other suitable multiple access mechanisms.

The transceiver 210 includes an energy harvester device 215 that can harvest energy from RF signals and other sources of electromagnetic radiation in a vicinity of the wireless device 200. The energy harvester device 215 can convert the harvested energy into a voltage (V_{HARV}) or a current that can power one or more components of the wireless device 200. In some aspects, the energy harvester 215 may also provide envelope information associated with received RF signals. The RF envelope information may indicate a magnitude, a power density, or other metric associated with the received RF signal.

In some implementations, the transceiver 210 may include a wake-up receiver (not shown for simplicity) configured to receive on-off keying (OOK) modulated RF signals. On-off keying uses the presence and absence of RF energy to encode data within the RF signal. For example, another wireless device may transmit an RF signal containing a relatively high amount of RF energy to indicate a first logical state (e.g., a logical one), and may transmit an RF signal containing a relatively low amount of RF energy to indicate a second logical state (e.g., a logical zero). The wake-up receiver can detect the energy level of an RF signal received from the other wireless device and determine the logical state indicated by the RF signal. A group of logical states indicated by such a signal can be used to identify and wake-up the wireless device 200. Although RF signals that convey information using an OOK mechanism can be modulated according to Wi-Fi, Bluetooth, BLE, or some other communication protocol, these RF signals can also use an unmodulated carrier signal within a frequency band from which the wake-up receiver is able to detect the presence (or absence) of RF energy. As such, the wake-up receiver does not need to demodulate received RF signals, but instead may receive and decode RF signals simply by detecting the presence or absence of RF energy on a wireless medium. In some aspects, the wake-up receiver may identify RF signals by correlating the detected RF energy with known energy patterns.

In other implementations, the transceiver 210 may include a plurality of energy harvester devices 215 (not shown for simplicity). For example, in some aspects, each of the radio chains 212(1)-212(n) may be associated with a corresponding energy harvester device 215. Additionally, the client device 200 also may include an antenna routing switch (not shown for simplicity) to flexibly couple any feasible antenna to any feasible power harvester. In other aspects, some or all of the radio chains 212(1)-212(n) may be associated with multiple energy harvester devices 215. In some other implementations, the energy harvester device 215 may be separate from or located external to the transceiver 210.

The baseband processor 220 is coupled to the transceiver 210 via one or more signal lines 222, is coupled to the memory 230 via one or more signal lines 224 and is coupled to the I/O interface 240 via one or more signal lines 226. The baseband processor 220 may be used to process signals received from the memory 230 and to forward the processed signals to the transceiver 210 for transmission via one or more of the antennas 202(1)-202(n). The baseband processor 220 may also be used to process signals received from one or more of the antennas 202(1)-202(n) via the transceiver 210 and to forward the processed signals to the memory 230. The baseband processor 220 may be any suitable processor capable of executing scripts or instructions of one or more software programs stored in the device 200 (e.g., within memory 230). In some implementations, the baseband processor 220 may be or may include one or more microprocessors providing the processor functionality and external memory providing at least a portion of machine-readable media. In other implementations, the baseband processor 220 may be or may include an Application Specific Integrated Circuit (ASIC) with the processor, the bus interface, the user interface, and at least a portion of the machine-readable media integrated into a single chip. In some other implementations, the processor 220 may be or include one or more Field Programmable Gate Arrays (FPGAs) or Programmable Logic Devices (PLDs). In some aspects, the baseband processor 220 may manage radio functions for the wireless device 200.

The memory 230 may include a database 232 that can store profile information for the wireless device 200 and/or profile information for other wireless devices. The database 232 may also store capabilities, parameters, and/or configuration information for the wireless device 200 and/or for other wireless devices. The memory 230 may also include a non-transitory computer-readable medium (e.g., one or more nonvolatile memory elements, such as EPROM, EEPROM, Flash memory, a hard drive, etc.) that may store instructions 234 for execution by the baseband processor 220. For example, the baseband processor 220 can execute the instructions 234 to perform various operations associated with the wireless device 200 and format frames carrying data, commands, capabilities, parameters, and other information for transmission to one or more other wireless devices. The baseband processor 220 can also execute the instructions to control energy harvesting mechanisms associated with the wireless device 200.

The battery 250 may be any suitable battery or charge-storing device that stores a voltage that can be used to power various circuits and components associated with the wireless device 200. In the example of FIG. 2, the battery 250 may be charged using energy harvested from RF signals by the energy harvester 215 or may be charged using a voltage provided by an external USB connection 270. In some instances, the battery 250 may be a lithium-ion battery or other type of lithium-based battery that provides a relatively high operating voltage (such as 4.6V). In other instances, the battery 250 may be a low-voltage battery such as a nickel-cadmium “coin” battery that provides a relatively low operating voltage (such as 3.3V). In some aspects, the relatively high voltage may be as high as 4.6V, and the relatively low voltage may be less than 3.3V.

The wireless device 200 may include a small charge store device 255 that can store enough charge to power at least some components of the wireless device 200. In some instances, the small charge store device 255 may be used to charge the battery 250. In various aspects, the small charge store device 255 may be a capacitor or a super-capacitor having a capacitance between 100-400 μF.

The power management circuit 260 includes a first input to receive a configuration bitstream from the memory 230, a second input coupled to the energy harvester 215, a first I/O port coupled to the battery 250, a second I/O port coupled to the small charge store device 255 a third I/O port that can be connected to an external USB connection 270 capable of providing a supply voltage (V_{USB}) to the power management circuit 260, and an output to provide a supply voltage (VDD) to various components (such as the transceiver 210, the baseband processor 220, the memory 230, and the power management circuit 260 via respective power rails (not shown for simplicity). The configuration bitstream, which may be stored in a suitable non-volatile memory (not shown for simplicity) within or associated with memory 230, includes configuration data that indicates at least the battery type, the maximum operating voltage, and the charging procedure of the battery 250. For example, for instances in which the battery 250 is a lithium-ion battery, the configuration data may indicate that the battery 250 is lithium-ion based, the battery 250 uses a charging procedure that includes a constant current mode and a constant voltage mode, and the maximum operating voltage of the battery 250, among other examples. The configuration data may also indicate the maximum charging current that can be used during the constant current mode of the charging procedure and the minimum charging current that can be used during the constant voltage mode of the charging procedure.

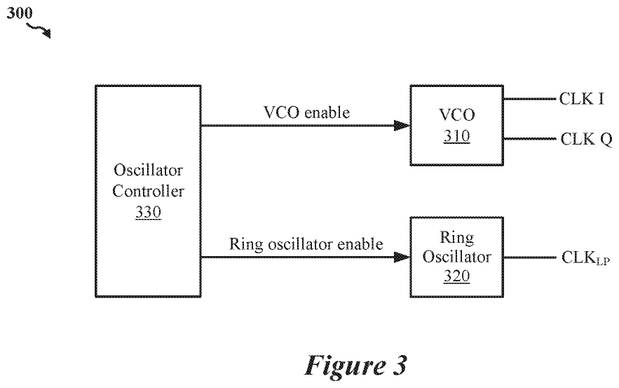

FIG. 3 shows a block diagram of a clock system 300 that can be used in the wireless device of FIG. 2 (the clock system 300 is not shown in FIG. 2 for simplicity). The clock system 300 may include a voltage controlled oscillator (VCO) 310, a ring oscillator 320, and an oscillator controller 330. The clock system 300 may provide clock signals for the radio chains 212(1)-212(n), the processor 220, the memory 230, and other components of the wireless device 200. In some implementations, the VCO 310 may be an oscillator with low phase noise that can generate very accurate clock signals such as an in-phase (I) clock signal CLK_I and a quadrature (Q) clock signal CLK_Q. The ring oscillator 320, which consumes less power but has higher phase noise than the VCO 310, may generate a low-power clock signal CLK_{LP}. Although not shown for simplicity, the ring oscillator 320 may also generate low-power I and Q clock signals.

The oscillator controller 330 may control operations of the VCO 310 and the ring oscillator 320 for the wireless device 200. For example, when the wireless device 200 operates in a normal power mode, the oscillator controller 330 may enable the VCO 310 and disable the ring oscillator 320, thereby enabling the clock system 300 to generate very accurate clock signals with low phase noise, albeit with a relatively high level of power consumption. Conversely, when the wireless device 200 operates in a low-power state, the oscillator controller 330 may enable the ring oscillator 320 and disable the VCO 310, thereby enabling the clock system 300 to generate less accurate clock signals having high phase noise clock while reducing power consumption (as compared with the normal power mode).

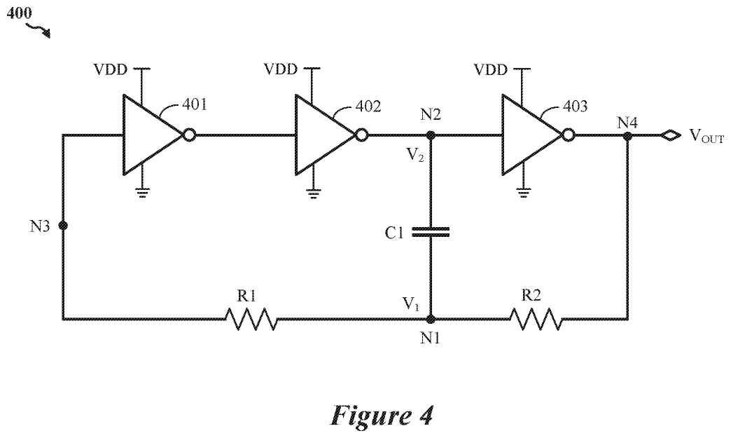

FIG. 4 shows a block diagram of a ring oscillator 400 that can be used as the ring oscillator 320 of FIG. 3. The ring oscillator 400 is shown to include three CMOS inverters 401-403 connected in series between node N3 and node N4, with node N4 providing an output voltage V_{OUT}. Each of the CMOS inverters 401-403 includes power terminals coupled to a supply voltage (VDD) and ground. A first resistor R1 is coupled between node N1 and N3, a second resistor R2 is coupled between node N4 and N1, and a capacitor C1 is coupled between node N2 and node N1. The voltage level at node N2 is denoted as V₂, and the voltage level at node N1 is denoted as V₁. The ring oscillator 400 operates as a relaxation oscillator in which the frequency of the output signal V_{OUT} is based on the RC time constant associated with R1, R2, and C1.

In some implementations, inverter 401 operates as a comparator that toggles its output between logic low and logic high states when an input signal at node N3 crosses a threshold voltage. For example, the inverter 401 drives its output signal to logic low in response to the input signal being in a logic low state (e.g., less than the threshold voltage). When the input signal rises above the threshold voltage, the inverter 401 drives its output signal to logic high. The inverter 401 maintains its output signal in the logic high state as long as the input signal remains above the threshold voltage. When the input signal falls below the threshold voltage, the inverter 401 drives its output signal to logic low. The output signal generated by the first CMOS inverter 401 is buffered by the second and third CMOS inverters 402-403 and provided as the output signal V_{OUT} of the ring oscillator 400 at node N4. An RC time constant associated with resistors R1-R2 and capacitor C1 determine the oscillation frequency of the ring oscillator 400.

The switching speed and latencies associated with the CMOS inverters 401-403, as well as the oscillation frequency of the ring oscillator 400, are dependent on the value of VDD. Specifically, when the voltage level of VDD increases, the switching speed of the CMOS inverters 401-403 increases, latencies associated with the CMOS inverters 401-403 decrease, and the oscillation frequency increases. Conversely, when the voltage level of VDD decreases, the switching speed of the CMOS inverters 401-403 decreases, latencies associated with the CMOS inverters 401-403 increase, and the oscillation frequency decreases. As a result, the frequency of clock signals based on or derived from the ring oscillator 400 changes in response to variations in VDD, thereby degrading the accuracy and stability of such clock signals. Moreover, when the ring oscillator 400 is used in low-power applications (e.g., when VDD<approximately 3.3 volts), latencies associated with CMOS inverters 401-403 typically increase. Therefore, there is a need for a ring oscillator that is less susceptible to variations in VDD.

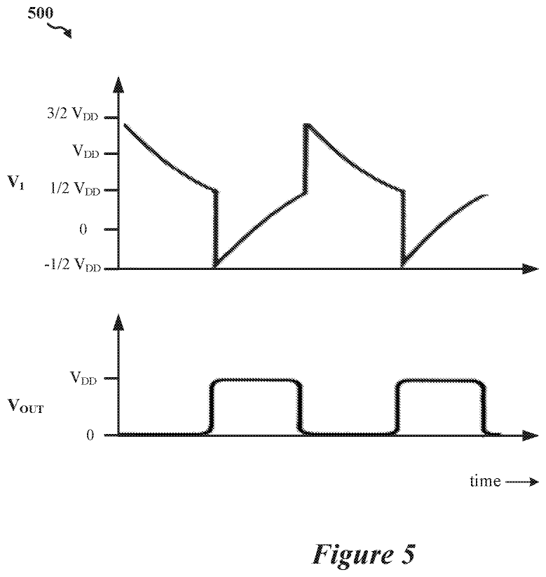

FIG. 5 shows a graph 500 depicting an input voltage waveform 510 and an output voltage waveform 520 associated with the ring oscillator 400 of FIG. 4. As shown, the input voltage waveform 510 decays from approximately 3*VDD/2 to approximately VDD/2 according to the RC time constant of the ring oscillator 400, and then drops to approximately −VDD/2. When the input voltage V₁ drops below approximately VDD/2, the output voltage V_{OUT} transitions from logic low (0 volts) to logic high (VDD). The logic high state of V_{OUT} causes the input voltage V₁ to increase from approximately −VDD/2 to approximately VDD/2 according to the RC time constant of the ring oscillator 400, and then increases to approximately 3*VDD/2.

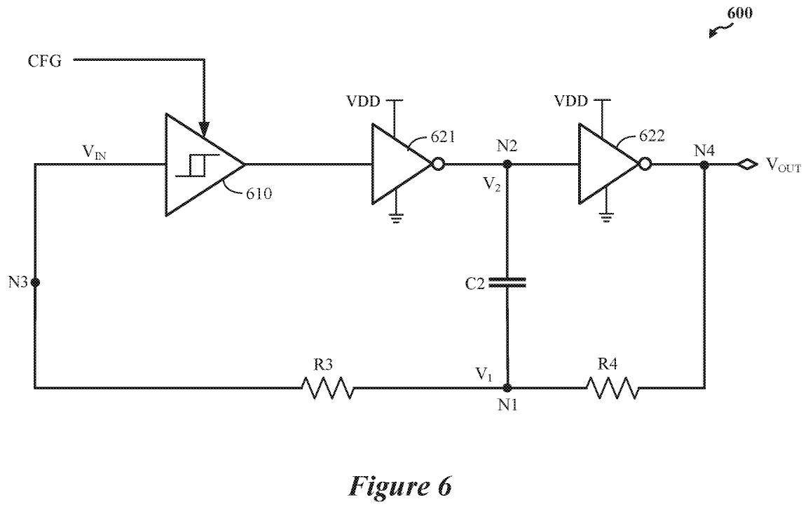

FIG. 6 shows a block diagram of an example programmable ring oscillator 600, according to some implementations. In some instances, the ring oscillator 600 may be one example of the ring oscillator 320 of FIG. 3. The ring oscillator 600 is shown to include a Schmitt trigger 610, two CMOS inverters 621-622, resistors R3 and R4, and a capacitor C2. The Schmitt trigger 610 includes an input coupled to node N3, an output coupled to an input of CMOS inverter 621, and a control input to receive a configuration signal CFG. CMOS inverters 621-622 are coupled in series between the Schmitt trigger 610 and node N4, which provides an output signal V_{OUT} for the ring oscillator 600. In some instances, the Schmitt trigger 610 and CMOS inverters 621-622 each include power terminals coupled to VDD and ground. Resistors R3 and R4 are coupled in series between node N4 and node N3, and capacitor C2 is coupled between node N1 and node N2. The voltage on node N1 is denoted as V₁, and the voltage on node N2 is denoted as V₂. In some aspects, the ring oscillator 600 may operate as a relaxation oscillator in which the frequency of the output signal V_{OUT} (f_{OUT}) is based on an RC time constant τ, where τ=(R3+R4)*C2.

In some implementations, the Schmitt trigger 610 operates as an inverting comparator having input hysteresis that includes a low threshold voltage V_{L} and a high threshold voltage V_{H}. For example, when the input voltage V_{IN} to the Schmitt trigger 610 is in a logic low state, the Schmitt trigger 610 drives its output to a logic high state. In response thereto, CMOS inverters 621-622 drive the output signal V_{OUT} to a logic high state. After a time delay approximately equal to 1/τ, the logic high state of the output signal V_{OUT} propagates through resistors R3 and R4 and drives the input voltage V_{IN} to the Schmitt trigger 610 to logic high. Specifically, when the input voltage V_{IN} increases to a level greater than the high threshold voltage V_{H}, the Schmitt trigger 610 drives its output to a logic low state. In response thereto, CMOS inverters 621-622 drive the output signal V_{OUT} to a logic low state, thereby transitioning the output signal V_{OUT} from logic high to logic low. In some aspects, the Schmitt trigger 610 maintains its output in the logic low state as long as V_{IN} remains greater than the low threshold voltage V_{L}.

After a time delay approximately equal to 1/τ, the logic low state of the output signal V_{OUT} propagates through resistors R3 and R4 and drives the input voltage V_{IN} to the Schmitt trigger 610 to logic low. Specifically, when the input voltage V_{IN} decreases to a level less than the low threshold voltage V_{L}, the Schmitt trigger 610 drives its output to a logic high state. In response thereto, CMOS inverters 621-622 drive the output signal V_{OUT} to a logic high state, thereby transitioning the output signal V_{OUT} from logic low to logic high. The input hysteresis associated with the Schmitt trigger 610 may be programmed or dynamically adjusted to compensate for variations in VDD, for example, such that the oscillation frequency f_{OUT} remains constant (or at least within a certain amount of a constant value) in the presence of variations in VDD. In some instances, the CMOS inverters 621-622 are low-power inverters with inherent latencies and/or signal transition delays having a known or configurable proportional relationship with the value of VDD, and the configuration signal can be used to program, set, or adjust the low threshold voltage V_{L} and the high threshold voltage V_{H} based on an instantaneous value of VDD, changes in the value of VDD, or both. In some instances, the logic low state of V_{OUT} may correspond to approximately 0 volts, and the logic high state of V_{OUT} may correspond to approximately VDD. In some aspects, the low threshold voltage V_{L} may be between 0 volts and VDD/2 and the high threshold voltage V_{H} may be between VDD/2 and VDD, where V_{L}<V_{H}.

In some implementations, the total amount of hysteresis associated with the Schmitt trigger 610 may be proportional to a measured or sensed value of VDD. When the value of VDD increases or is relatively high, latencies associated with the CMOS inverters 621-622 decrease while voltage swings associated with logic state transitions in the CMOS inverters 621-622 increase, which in turn increases the oscillation frequency. The increased or relatively high value of VDD causes the input hysteresis associated with the Schmitt trigger 610 to increase or widen, for example, such that the low threshold voltage V_{L} decreases from its initial value and the high threshold voltage V_{H} increases from its initial value. As a result, node N3 must discharge to a lower voltage (e.g., lower than V_{L}) to trigger high-to-low transitions of the Schmitt trigger 610 and must charge to a higher voltage (e.g., greater than V_{H}) to trigger low-to-high transitions of the Schmitt trigger 610, thereby decreasing the oscillation frequency in a manner that compensates for the increase in oscillation frequency resulting from higher values of VDD.

Conversely, when the value of VDD decreases or is relatively low, latencies associated with the CMOS inverters 621-622 increase while voltage swings associated with logic state transitions in the CMOS inverters 621-622 decrease, which in turn decreases the oscillation frequency. The decreased or relatively low value of VDD causes the input hysteresis associated with the Schmitt trigger 610 to decrease or narrow, for example, such that the low threshold voltage V_{L} increases from its initial value and the high threshold voltage V_{H} decreases from its initial value. As a result, node N3 does not need to discharge as much (compared to the initial value of V_{L}) to trigger high-to-low transitions of the Schmitt trigger 610 and does not need to charge as must (compared to the initial value of V_{H}) to trigger low-to-high transitions of the Schmitt trigger 610, thereby increasing the oscillation frequency in a manner that compensates for the decrease in oscillation frequency resulting from lower values of VDD.

In this way, aspects of the subject matter disclosed herein can maintain the oscillation frequency at a constant value (or at least within a certain amount of the constant value) in response to changes in VDD. In some instances, an increase in VDD may cause the Schmitt trigger's input hysteresis to increase by an amount that reduces the oscillation frequency by an amount or percentage equal to (or at least within a certain amount of) the increase in oscillation frequency resulting from the increase in VDD, and a decrease in VDD may cause the Schmitt trigger's input hysteresis to decrease by an amount that increases the oscillation frequency by an amount or percentage equal to (or at least within a certain amount of) the decrease in oscillation frequency resulting from the decrease in VDD.

After a time delay approximately equal to 1/τ, the logic high state of the output signal V_{OUT} propagates through resistors R3 and R4 and drives the input voltage V_{IN} to the Schmitt trigger 610 to logic high. As discussed, when the input voltage V_{IN} increases to a level greater than the high threshold voltage V_{H}, the Schmitt trigger 610 drives its output to a logic low state and CMOS inverters 621-622 drive the output signal V_{OUT} to a logic low state, thereby transitioning the output signal V_{OUT} from logic high to logic low. In this way, aspects of the present disclosure may reduce variations in the oscillation frequency caused by variations in the supply voltage VDD, thereby increasing the accuracy of clock signals based on or derived from the ring oscillator 600.

In some implementations, the configuration signal CFG may be used to adjust the values of the low threshold voltage V_{L} and the high threshold voltage V_{H} associated with the Schmitt trigger 610. In some aspects, the wireless device 200 may adjust the hysteresis associated with the ring oscillator 600 based on various operating conditions such as (but not limited to) operating temperature, operating voltage, and low-power state parameters, among other examples. As described above, the configuration signal can be used to program, set, or adjust the low threshold voltage V_{L} and the high threshold voltage V_{H} based on VDD.

In some instances, when the operating temperature decreases or is relatively low, the wireless device 200 can generate first values of the configuration signal that decrease the value of the low threshold voltage V_{L} and increase the value of the high threshold voltage V_{H}. Conversely, when the operating temperature increases or is relatively high, the wireless device 200 can generate second values of the configuration signal that increase the value of the low threshold voltage V_{L} and decrease the value of the high threshold voltage V_{H}.

In other instances, when the operating voltage decreases or is relatively low, the wireless device 200 can generate first values of the configuration signal that increase the value of the low threshold voltage V_{L} and decrease the value of the high threshold voltage V_{H}. Conversely, when the operating voltage increases or is relatively high, the wireless device 200 can generate second values of the configuration signal that decrease the value of the low threshold voltage V_{L} and increase the value of the high threshold voltage V_{H}.

In some other instances, when the low-power state parameters are in a first state or have first values, the wireless device 200 can generate first values of the configuration signal that decrease the value of the low threshold voltage V_{L} and increase the value of the high threshold voltage V_{H}. Conversely, when the low-power state parameters are in a second state or have second values, the wireless device 200 can generate second values of the configuration signal that increase the value of the low threshold voltage V_{L} and decrease the value of the high threshold voltage V_{H}.

As used herein, a phrase referring to “at least one of” or “one or more of” a list of items refers to any combination of those items, including single members. For example, “at least one of: a, b, or c” is intended to cover the possibilities of: a only, b only, c only, a combination of a and b, a combination of a and c, a combination of b and c, and a combination of a and b and c. As used herein, “based on” is intended to be interpreted in the inclusive sense, unless otherwise explicitly indicated. For example, “based on” may be used interchangeably with “based at least in part on,” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The various illustrative components, logic, logical blocks, modules, circuits, operations, and algorithm processes described in connection with the implementations disclosed herein may be implemented as electronic hardware, firmware, software, or combinations of hardware, firmware, or software, including the structures disclosed in this specification and the structural equivalents thereof. The interchangeability of hardware, firmware and software has been described generally, in terms of functionality, and illustrated in the various illustrative components, blocks, modules, circuits and processes described herein. Whether such functionality is implemented in hardware, firmware or software depends upon the application and design constraints imposed on the overall system.

Various modifications to the implementations described in this disclosure may be readily apparent to persons having ordinary skill in the art, and the generic principles defined herein may be applied to other implementations without departing from the spirit or scope of this disclosure. Thus, the claims are not intended to be limited to the implementations shown herein but are to be accorded the widest scope consistent with this disclosure, the principles and the novel features disclosed herein.

Additionally, various features that are described in this specification in the context of separate implementations also can be implemented in combination in a single implementation. Conversely, various features that are described in the context of a single implementation also can be implemented in multiple implementations separately or in any suitable subcombination. As such, although features may be described herein as acting combinations, and even initially claimed as such, one or more features from a claimed combination can in some instances be excised from the combination, and the claimed combination may be directed to a subcombination or variation of a subcombination.

Similarly, while operations are depicted in the drawings in a particular order, this should not be understood as requiring that such operations be performed in the order shown or in sequential order, or that all illustrated operations be performed, to achieve desirable results. Further, the drawings may schematically depict one or more example operations in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the implementations described herein should not be understood as requiring such separation in all implementations, and the described program components and systems can generally be integrated together in a single software product or packaged into multiple software products.

What is claimed is:

1. A programmable ring oscillator, comprising:
a Schmitt trigger including an input coupled to a first node, a control terminal coupled to a configuration signal, and an output;
a first CMOS inverter including an input coupled to the output of the Schmitt trigger and an output coupled to a second node;
a second CMOS inverter including an input coupled to the second node and an output coupled to an output terminal of the programmable ring oscillator, the output terminal configured to provide an output signal having a oscillating frequency;
a first resistor coupled between the output terminal and a third node;
a second resistor coupled between the third node and the first node; and
a capacitor coupled between the second node and the third node.

2. The programmable ring oscillator of claim 1, wherein the programmable ring oscillator comprises a relaxation oscillator.

3. The programmable ring oscillator of claim 1, wherein the oscillating frequency is based on an RC time constant of the first resistor, the second resistor, and the capacitor.

4. The programmable ring oscillator of claim 1, wherein the Schmitt trigger comprises an inverting comparator.

5. The programmable ring oscillator of claim 1, wherein:
the Schmitt trigger includes power terminals coupled to a supply voltage and ground potential; and
the Schmitt trigger includes input hysteresis having a relatively low threshold voltage and a relatively high threshold voltage.

6. The programmable ring oscillator of claim 5, wherein the relatively low threshold voltage is equal to ground potential and the relatively high threshold voltage is equal to the supply voltage.

7. The programmable ring oscillator of claim 5, wherein the relatively low threshold voltage is equal to a first voltage between ground potential and one-half the supply voltage, and the relatively high threshold voltage is equal to a second between one-half the supply voltage and the supply voltage.

8. The programmable ring oscillator of claim 5, wherein a difference between the relatively low threshold voltage and the relatively high threshold voltage is proportional to the supply voltage.

9. The programmable ring oscillator of claim 5, wherein the relatively low threshold voltage and the relatively high threshold voltage are based on one or more values of the configuration signal.

10. The programmable ring oscillator of claim 9, wherein the one or more values of the configuration signal are based at least in part on an instantaneous value of the supply voltage, changes in the supply voltage, or both.

11. The programmable ring oscillator of claim 10, wherein:
when the supply voltage decreases or is relatively low, the one or more values of the configuration signal are in a first state that causes the relatively low threshold voltage to increase and causes the relatively high threshold voltage to decrease; and
when the supply voltage increases or is relatively high, the one or more values of the configuration signal are in a second state that causes the relatively low threshold voltage to decrease and causes the relatively high threshold voltage to increase.

12. The programmable ring oscillator of claim 9, wherein the one or more values of the configuration signal are based at least in part on an operating temperature of the programmable ring oscillator.

13. The programmable ring oscillator of claim 12, wherein:
when the operating temperature decreases or is relatively low, the one or more values of the configuration signal are in a first state that causes the relatively low threshold voltage to decrease and causes the relatively high threshold voltage to increase; and
when the operating temperature increases or is relatively high, the one or more values of the configuration signal are in a second state that causes the relatively low threshold voltage to decrease and causes the relatively high threshold voltage to increase.

14. The programmable ring oscillator of claim 9, wherein the one or more values of the configuration signal are based at least in part on low-power parameters associated with a wireless device.

15. The programmable ring oscillator of claim 14, wherein:
when the low-power parameters are in a first state or have first values, one or more values of the configuration signal are in a first state that causes the relatively low threshold voltage to decrease and causes the relatively high threshold voltage to increase; and
when the low-power parameters are in a second state or have second values, the one or more values of the configuration signal are in a second state that causes the relatively low threshold voltage to increase and causes the relatively high threshold voltage to decrease.
